(19) United States
(12) Patent Application Publication
(10) Pub. No.: US 2004/0007780 A1
(43) Pub. Date: Jan. 15, 2004

(54) Particle-filled semiconductor attachment material

(76) Inventors: Paul Joseph Hundt, Garland, TX (US); Leon Stiborek, Dallas, TX (US)

Correspondence Address: TEXAS INSTRUMENTS INCORPORATED, P O BOX 655474, M/S 3999, DALLAS, TX, 75265

(21) Appl. No.: 10/192,004

(22) Filed: Jul. 9, 2002

(51) Int. Cl. H01L 21/44; H01L 23/58; H01L 29/40

(52) U.S. Cl. 257/782; 257/633; 257/706; 257/707; 438/125; 438/118

(57) ABSTRACT

Disclosed is a high thermal conductance attachment mixture for semiconductor package assembly which includes high thermal conductance particles suspended in reflowable material. The high thermal conductance particles have a high melting point relative to the reflowable material and comprise approximately 50% to approximately 95% by volume of the high thermal conductance attachment mixture. Also disclosed is a semiconductor package including the high thermal conductance attachment mixture. An associated method of attaching adjoining layers of a semiconductor die package using a high thermal conductance attachment mixture is also disclosed.

### TECHNICAL FIELD

The present invention relates in general to providing semiconductor integrated circuit (IC) packages with improved junction-to-case thermal conductivity. More particularly, the invention relates to semiconductor package die-to-lid attachment material and associated methods providing high thermal conductivity domains distributed throughout the attachment material.

### BACKGROUND OF THE INVENTION

Thermal conductivity is known generally as the quantity of heat transmitted in a direction normal to a surface of unit area. Thermal conductivity is sometimes a factor in the implementation of semiconductor package designs. In flip chip packaging technology for example, an alumina substrate typically underlays a semiconductor die attached thereto with solder ball connections and a nonconductive underfill material. It is known in the arts to attach a package lid to the top surface of the die using an epoxy or similar chemical adhesive attachment material.

The performance of flip chip ICs can be detrimentally affected by insufficient thermal conductivity between the active side of the chip and the upper surface of the package lid. Two factors affecting thermal conductivity are the bulk conductivity of the package materials and the contact resistance between adjacent layers of package material. The attachment material known in the art often has notably poor bulk thermal conductivity properties, and necessarily has two junctions with the adjacent layers producing contact resistance. Frequently another factor detrimentally affecting thermal conductivity is the presence of voids in the attachment material between layers of the device.

One approach to addressing these and other problems in order to provide improved thermal conductivity is to use a thinner layer of attachment material between the semiconductor die and package lid. A thinner layer of attachment material inherently possesses a lower thermal resistance than a thicker layer. A thin layer is more vulnerable to mechanical stresses, however, which can introduce additional problems with component reliability. Another approach known in the art is to include small solder spheres within a chemical adhesive, such as epoxy, in an effort to reduce contact resistance.

Efforts to improve thermal conductivity and reduce contact resistance have not been entirely satisfactory. Reflowed solder and hardened chemical adhesives are generally relatively poor thermal conductors. Attachments made using such materials are often further hampered by high contact resistance and a tendency to allow void formation. What is needed in the art is a high conductivity attachment material with advantageous bulk conductivity and contact resistance properties which is capable of providing secure bonds with reduced voids. Further advantages would inhere in improved attachment material adaptable for use with current manufacturing equipment processes and techniques.

### SUMMARY OF THE INVENTION

In carrying out the principles of the present invention, in accordance with an embodiment thereof, a high thermal conductance attachment mixture for semiconductor package assembly is provided which includes high thermal conductance particles suspended in reflowable material. The high thermal conductance particles have a high melting point relative to the reflowable material.

According to one aspect of the invention, the high thermal conductance attachment mixture may have a high thermal conductance particle content from approximately 50% to approximately 95% by volume.

In another aspect of the invention, the high thermal conductance attachment mixture may have high thermal conductance particles from approximately 10³ cubic micrometers to approximately 75³ cubic micrometers in size.

According to another aspect of the invention, the high thermal conductance attachment mixture may include one or more or a combination of, silver, copper, gold, or other metals.

According to one aspect of the invention, a method of attaching adjoining layers of a semiconductor die package using a high thermal conductance attachment mixture therebetween is disclosed. The high thermal conductance attachment mixture is positioned and heated to form a secure highly thermally conductive bond.

These and other features, advantages, and benefits of the present invention will become apparent to one of ordinary skill in the art upon careful consideration of the detailed description of a representative embodiment of the invention in connection with the accompanying drawings.

### BRIEF DESCRIPTION OF THE DRAWINGS

The present invention will be more clearly understood from consideration of the following detailed description and drawings in which:

FIG. 1 is a cross-section view of an example of a semiconductor package using a preferred embodiment of the invention;

FIG. 2 is a top view of the semiconductor package of FIG. 1 cut-away along line 2-2 showing an example of high thermal conductance attachment mixture of the invention;

FIG. 3 is top view illustrating an example of the deployment of high thermal conductance attachment mixture in an example of a preferred embodiment of the invention; and

FIG. 4 is a process flow diagram showing steps in a preferred method of the invention.

References in the detailed description correspond to like references in the figures unless otherwise noted. Like numerals refer to like parts throughout the various figures. Descriptive and directional terms used in the written description such as top, bottom, left, right, etc., refer to the drawings themselves as laid out on the paper and not to physical limitations of the invention unless specifically noted. The drawings are not to scale and some features of embodiments shown and discussed are simplified or exaggerated for illustrating the principles, features, and advantages of the invention.

### DETAILED DESCRIPTION OF PREFERRED EMBODIMENTS

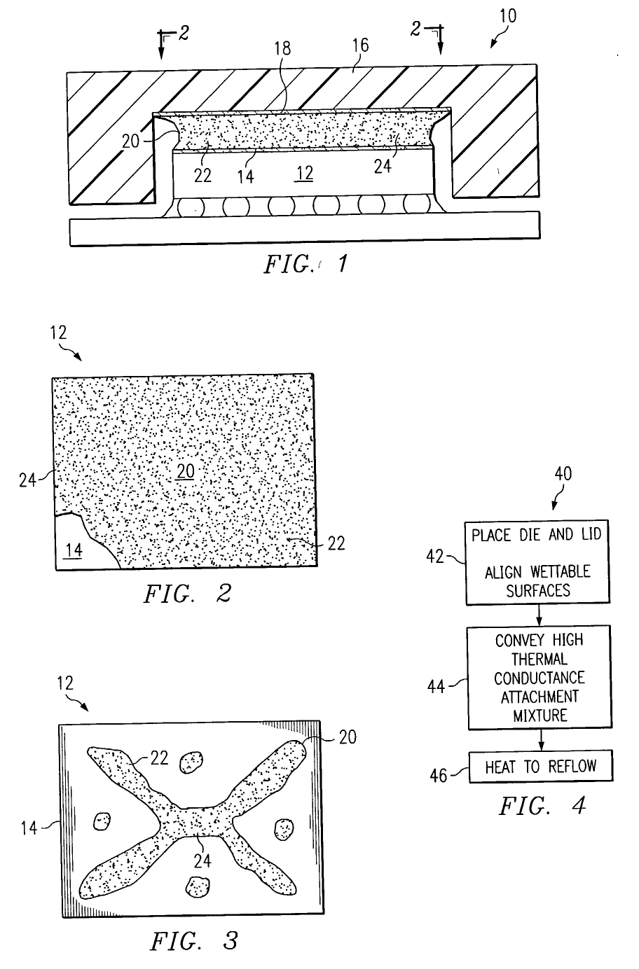

It has been observed that the layer of material commonly used for attaching a package lid to a semiconductor die is susceptible to improvements in thermal conductivity. Representatively illustrated in FIG. 1, a cross-section view shows an example of the use of a preferred embodiment of the invention. In a semiconductor device package 10, the semiconductor die 12 has a wettable surface 14, typically layers of metal or alloy such as chrome-nickel-silver. The package lid 16 has a wettable surface 18 disposed adjacent to the wettable surface 14 of the semiconductor die 12, typically a thin layer of nickel or gold, although other metals or alloys are sometimes used. Various semiconductor dice and lids, or other types of layers, having wettable surfaces are known in the arts and may be used or adapted for use as described without departure from the concept of the present invention.

A high thermal conductance attachment mixture 20 is disposed between the adjacent wettable lid 16 and die 12 surfaces 14, 18 for providing a secure and highly thermally conductive attachment. Preferably, the high thermal conductance attachment mixture 20 has highly thermally conductive metal particles 22, such as silver, making up approximately 50% to approximately 95% of the high thermal conductance attachment mixture 20 by volume. Other highly thermally conductive particles or combinations of particles may be used such as, for example, copper or gold, provided that such particles have a high melting point relative to a reflowable material 24 of the high thermal conductance attachment mixture 20. The reflowable material 24 is preferably a solder material commonly known in the arts such as tin-lead or tin-silver solder. Preferably the reflowable material 24 makes up approximately 5% to approximately 50% of the high thermal conductance attachment mixture 20 by volume.

It is preferred that the high thermal conductance particles 22 are sized such that they form highly thermally conductive paths between the wettable surfaces 14, 18 of the semiconductor die 12 and the package lid 16. Presently, high thermal conductance particles 22 of approximately 10² μm to approximately 75² μm in cross-sectional area are preferred. Alternative sizes of high thermal conductance particles may be used. According to the preferred embodiment of the invention, the reflowable material 24 wets to the high thermal conductance particles 22 as well as to the lid and die surfaces 14, 18. It is believed that the preferred embodiment of the invention reduces the potential for voids within the high thermal conductive attachment material 20 to sizes equal to or less than the high thermal conductance particle 22 sizes.

FIG. 2 is a top cutaway view taken along lines 2-2 of FIG. 1 showing a planar distribution of the high thermal conduction attachment mixture 20 of the invention positioned atop the wettable surface 14 (as shown in the corner portion of FIG. 2) of the semiconductor die 12. It should be understood that the high thermal conduction attachment mixture 20 of the invention may be implemented in the form of a paste or in the form of a pre-formed sheet, either of which may be used with common alternative versions of semiconductor package 10 fabrication techniques and apparatus. Thus, a preformed sheet of high thermal conduction attachment mixture 20 may be positioned at the wettable surface 14 of the die 12 (as shown in FIG. 2).

Alternatively, a preselected pattern of high thermal conduction attachment mixture paste 20 may be dispensed at the wettable surface 14 of the die 12 as shown in FIG. 3. In the case shown in the example of FIG. 3, the package lid (16, not shown) is aligned and placed according to techniques known in the art such that the high thermal conduction mixture paste 20 becomes evenly distributed when the lid 16 and the die 12 are brought together so that their wettable surfaces (14, 18) adjoin. In either event, the preferred distribution of the high thermal conduction attachment mixture 20 ultimately appears in a generally uniform layer as shown in FIGS. 1 and 2.

With the semiconductor die 12, high thermal conductivity attachment mixture 20, and lid 16 aligned as shown in FIG. 1, the package 10 is heated to a temperature sufficient to cause the reflowable material 24 to reflow, forming a metallic alloy bond between the wettable surfaces 14, 18 of the die 12 and lid 16. Preferably a metallic alloy bond is also formed among at least some of the high thermal conduction particles 22. The formation of a metallic alloy bond between at least some of the high thermal conduction particles 22 and the wettable die surface 14, or the wettable lid surface 18, depending on their proximity, is also preferred. Typically, the high thermal conductance attachment mixture 20 also includes a relatively small percentage of flux (not shown) for promoting the formation of metallic alloy bonds. It should be understood that flux may be included within the high thermal conductance attachment mixture 20, or may alternatively be separately applied to the wettable surface 14 of the die 12 and the wettable surface 18 of the lid 16. In the case of preformed sheets of the high thermal conductance attachment mixture 20, flux may alternatively be provided as an external coating of the preformed sheet.

FIG. 4 is a process flow diagram 40 depicting an example of steps in a preferred method of attaching a lid to a semiconductor die package within the principles of the invention. The wettable surfaces of the lid and die are placed in proximity and aligned 42 according to standard processes. In step 44, a high thermal conductance attachment mixture containing quantities of high thermal conductance particles and reflowable material is conveyed between the wettable surfaces of the die and lid using standard manufacturing techniques. The package is heated, in step 46, wetting the reflowable material of the high thermal conductance attachment mixture to the wettable surfaces of the lid and die, forming an attachment. It should be appreciated that the high thermal conductance attachment mixture may be placed in the form of a solid sheet or a paste as shown in FIG. 3. It should also be understood that the order in which the elements are positioned may be varied and that steps prior to the heating step of the example may be combined without departure from the concept of the invention.

Those skilled in the arts will appreciate that the presence of high thermal conductance particles that do not melt in the reflow process greatly increases the bulk thermal conductivity of the high thermal conductance attachment mixture. It should also be apparent that the formation of metallic alloy bonds between the adjoining lid and die surfaces reduces contact resistance. The higher bulk conductivity allows for the use of a thicker attachment material layer. The improved metallic alloy bonds also allow for the use of a thinner attachment material layer, according to the requirements of the application.

Thus, the invention provides high thermal conductivity domains distributed throughout the attachment of adjoining wettable surfaces, providing a secure attachment. While the invention has been described with reference to illustrative embodiments, this description is not intended to be construed in a limiting sense. Various modifications and combinations of the illustrative embodiments as well as other embodiments of the invention will be apparent to persons skilled in the art upon reference to the description and claims.

We claim:

1. A high thermal conductance attachment mixture for semiconductor package assembly comprising:
reflowable material for forming a metallic alloy bond; and
high thermal conductance particles mixed with the reflowable material, and
wherein the high thermal conductance particles have a melting point higher than that of the reflowable material.

2. A high thermal conductance attachment mixture according to claim 1, further comprising flux.

3. A high thermal conductance attachment mixture according to claim 1, comprising high thermal conductance particles less than or equal to approximately 95% by volume of the mixture.

4. A high thermal conductance attachment mixture according to claim 1, comprising high thermal conductance particles greater than or equal to approximately 50% by volume of the mixture.

5. A high thermal conductance attachment mixture according to claim 1, comprising high thermal conductance particles from approximately 50% to approximately 95% by volume of the mixture.

6. A high thermal conductance attachment mixture according to claim 1, wherein the high thermal conductance particles are greater than or equal to approximately 10³ cubic micrometers in size.

7. A high thermal conductance attachment mixture according to claim 1, wherein the high thermal conductance particles are less than or equal to approximately 75³ cubic micrometers in size.

8. A high thermal conductance attachment mixture according to claim 1, wherein the high thermal conductance particles are from approximately 10³ cubic micrometers to approximately 75³ cubic micrometers in size.

9. A high thermal conductance attachment mixture according to claim 1, wherein the high thermal conductance particles further comprise metal.

10. A high thermal conductance attachment mixture according to claim 1, wherein the high thermal conductance particles consist of at least one metal selected from the group, silver, copper, gold.

11. A high thermal conductance attachment mixture according to claim 1, wherein the high thermal conductance particles consist of silver.

12. A high thermal conductance attachment mixture according to claim 1, adapted to form a paste.

13. A high thermal conductance attachment mixture according to claim 1, adapted to form a solid.

14. A high thermal conductance attachment mixture for semiconductor package assembly comprising:
reflowable material for forming a metallic alloy bond;
from approximately 50% to approximately 95% by volume high thermal conductance particles from approximately 10³ cubic micrometers to approximately 75³ cubic micrometers in size mixed with the reflowable material,
wherein the high thermal conductance particles have a melting point higher than that of the reflowable material; and
flux suspended in the mixture.

15. A high thermal conductance attachment mixture according to claim 14, wherein the high thermal conductance particles comprise metal.

16. A high thermal conductance attachment mixture according to claim 14, wherein the high thermal conductance particles are selected from the group;
silver, copper, gold.

17. A high thermal conductance attachment mixture according to claim 14, wherein the high thermal conductance particles further comprise silver.

18. A semiconductor package comprising:
a semiconductor die having a wettable surface;
an adjoining lid having a wettable surface; and
disposed therebetween, a high thermal conductance attachment mixture comprising a reflowable material and high thermal conductance particles.

19. A semiconductor package according to claim 18, wherein the high thermal conductance attachment mixture further comprises high thermal conductance particles less than or equal to approximately 95% by volume of the mixture.

20. A semiconductor package according to claim 18, wherein the high thermal conductance attachment mixture further comprises high thermal conductance particles greater than or equal to approximately 50% by volume of the mixture.

21. A semiconductor package according to claim 18, wherein the high thermal conductance attachment mixture further comprises high thermal conductance particles from approximately 50% to approximately 95% by volume of the mixture.

22. A semiconductor package according to claim 18, wherein the high thermal conductance particles are greater than or equal to approximately 10³ cubic micrometers in size.

23. A semiconductor package according to claim 18, wherein the high thermal conductance particles are less than or equal to approximately 75³ cubic micrometers in size.

24. A semiconductor package according to claim 18, wherein the high thermal conductance particles are from approximately 75³ cubic micrometers to approximately 75 cubic micrometers in size.

25. A semiconductor package according to claim 18, wherein the high thermal conductance particles further comprise metal.

26. A semiconductor package according to claim 18, wherein the high thermal conductance particles consist of at least one metal selected from the group, silver, copper, gold.

27. A semiconductor package according to claim 18, wherein the high thermal conductance particles consist of silver.

28. A method attaching a first layer to a second layer of a semiconductor die package comprising the steps of:
aligning wettable surfaces of the first and second layers;
conveying a high thermal conductance attachment mixture therebetween, the high thermal conductance attachment mixture comprising a reflowable material and high thermal conductance particles; and
heating the high thermal conductance attachment mixture, thereby wetting the reflowable material of the high thermal conductance attachment mixture to the wettable surfaces of the first and second layers forming an attachment therebetween.

29. The method according to claim 28, wherein the conveying step further comprises placing a pre-formed solid high thermal conductance attachment mixture.

30. The method according to claim 28, wherein the conveying step further comprises dispensing a high thermal conductance attachment mixture paste.
